(19) United States
(12) Patent Application Publication
(10) Pub. No.: US 2024/0421613 A1
(43) Pub. Date: Dec. 19, 2024

(54) ELECTRONIC DEVICE AND METHOD FOR CONTROLLING BATTERY CHARGING IN THE ELECTRONIC DEVICE

(71) Applicant: Samsung Electronics Co., Ltd., Suwon-si (KR)

(72) Inventor: Kyunghwan LEE, Suwon-si (KR)

(21) Appl. No.: 18/742,518

(22) Filed: Jun. 13, 2024

Related U.S. Application Data
(63) Continuation of application No. PCT/KR2024/007998, filed on Jun. 11, 2024.

(30) Foreign Application Priority Data
Jun. 13, 2023 (KR) 10-2023-0075566
Aug. 22, 2023 (KR) 10-2023-0109994

(51) Int. Cl. H02J 7/00

(52) U.S. Cl. CPC H02J 7/00308; H02J 7/00714; H02J 7/007182; H02J 2207/20

(57) ABSTRACT

An electronic device according to an embodiment may include: a battery, load, charging circuitry, and control circuitry. The charging circuitry may include a plurality of switches and be configured to, in a PPS mode, receive power adjusted in each specified charging period according to a charge amount of the battery from an external electronic device, convert a voltage of the received power based on a specified voltage conversion ratio using the plurality of switches, and supply the voltage-converted power to the battery and the load. The control circuitry may be configured to: control a gate voltage of at least one specified switch of the plurality of switches, based on a voltage of the battery being higher than a maximum allowed charging voltage or a current of the battery being higher than a maximum allowed charging current during the PPS mode.

### CROSS-REFERENCE TO RELATED APPLICATIONS

This application is a continuation of International Application No. PCT/KR2024/007998 designating the United States, filed on Jun. 11, 2024, in the Korean Intellectual Property Receiving Office and claiming priority to Korean Patent Application Nos. 10-2023-0075566, filed on Jun. 13, 2023, and 10-2023-0109994, filed on Aug. 22, 2023, in the Korean Intellectual Property Office, the disclosures of each of which are incorporated by reference herein in their entireties.

### BACKGROUND

### Field

The disclosure relates to a method for controlling battery charging in an electronic device.

### Description of Related Art

The remarkable development of information and communication technology and semiconductor technology has led to a rapid increase in the popularity and use of various electronic devices such as smartphones and tablet PCs. In particular, recent electronic devices are capable of operating using power supplied by batteries.

A power management module (e.g., a power management integrated circuit (PMIC)) in an electronic device may transfer power from a battery to various components (e.g., a processor, memory, or a communication chip) inside the electronic device. The battery inside the electronic device may be charged with power supplied by an external electronic device (e.g., an external power device).

A variety of charging schemes, such as wired charging, wireless charging, normal charging, and/or fast charging, may be applied to recent electronic devices.

Among various charging schemes, direct charging may allow an external electronic device (e.g., an external power device or a programmable power supply (PPS)-supporting device) to perform constant voltage or constant current control of a battery inside an electronic device. For example, direct charging may be a scheme in which an external power device changes a voltage and/or a current in each specified charging period according to a charge amount of the battery in the electronic device, and the electronic device receives power corresponding to the voltage and/or current changed by the external power device and charges the battery with the received power. Other charging schemes other than direct charging may include, for example, an adaptive fast charge (AFC) scheme in which constant voltage or constant current control of a battery inside an electronic device is performed by a charging circuit of the electronic device rather than by an external power device.

To reduce the installation area of a charging circuit and cost, an electronic device may include a charging circuit (e.g., a hybrid charger or hybrid charging circuit) that operates in the direct charging scheme (or mode), when power is received from a PPS-supporting external power device, and operates in a different charging scheme (or mode) (e.g., the AFC scheme), when power is received from an external power device that does not support PPS.

When operating in the direct charging mode, the charging circuit of the electronic device may supply power to a load (e.g., system) and supply power for charging the battery, using power provided according to a voltage and a current (e.g., half of a voltage of the external power device and twice a current of the external power device) determined (or specified) by the external power device, with the switching frequency and duty ratio of the charging circuit each fixed at a specified value, without controlling the voltage and current of the battery and/or an input current.

Because when operating in the direct charging mode, the charging circuit is not capable of controlling the voltage and current of the battery and/or the input current, a current flowing in the load changes rapidly (e.g., from 2 A to 0 A) when a battery charging period transitions from a constant current (CC) to a constant voltage (CV) or during a CV period, which causes the voltage of the battery to be higher than a maximum allowed charging voltage. However, the battery voltage may not be controlled to decrease (e.g., for a few ms) until before the external power device decreases the voltage, thereby resulting in an overvoltage state.

### SUMMARY

Embodiments of the disclosure provide an electronic device and a method for controlling battery charging in which even when a charging circuit operates in the direct charging mode, may prevent and/or reduce an overvoltage from being applied to a battery by adjusting the resistance of a switch inside the charging circuit based on an input current received from an external power device, a battery voltage, and/or a battery current.

Embodiments of the disclosure provide an electronic device and a method for controlling battery charging in which even when a charging circuit operates in the direct charging mode, may prevent and/or reduce an overvoltage from being applied to a battery by adjusting both the resistance and duty ratio of a switch inside the charging circuit based on an input current received from an external power device, a battery voltage, and/or a battery current.

An electronic device according to an example embodiment includes: a battery, a load, charging circuitry, and control circuitry. The charging circuitry according to an example embodiment includes a plurality of switches, and is configured to: in a programmable power supply (PPS) mode, receive power adjusted in each specified charging period according to a charge amount of the battery from an external electronic device, convert a voltage of the received power based on a specified voltage conversion ratio using the plurality of switches, and supply the voltage-converted power to the battery and the load. The control circuitry according to an embodiment is configured to: control a gate voltage of at least one specified switch of the plurality of switches, based on a voltage of the battery being higher than a maximum allowed charging voltage or a current of the battery being higher than a maximum allowed charging current during the PPS mode.

A method for controlling charging of a battery in an electronic device including the battery, a load, charging circuitry, and control circuitry according to an example embodiment includes: identifying, through the control circuitry, that the charging circuitry receives power from an external electronic device supporting a programmable power supply (PPS) in a PPS mode. The method according to an example embodiment includes: identifying, through the control circuitry, whether a voltage of the battery is higher than a maximum allowed charging voltage or a current of the battery is higher than a maximum allowed charging current during supply of the charging current to the battery in the PPS mode; based on the voltage of the battery being higher than the maximum allowed charging voltage or the current of the battery being higher than the maximum allowed charging current, controlling, through the control circuitry, a gate voltage of each of at least one specified switch of a plurality of switches included in the charging circuitry.

In a non-transitory computer-readable storage medium storing instructions according to an example embodiment, the instructions, when executed by an electronic device, cause the electronic device to perform at least one operation. The at least one operation includes: identifying, through control circuitry, that a charging circuitry receives power from an external electronic device supporting a programmable power supply (PPS) in a PPS mode, identifying, through the control circuitry, whether a voltage of a battery is higher than a maximum allowed charging voltage during supply of the charging current to the battery in the PPS mode, and based on the voltage of the battery being higher than the maximum allowed charging voltage or a current of the battery being higher than a maximum allowed charging current, controlling, through the control circuitry, a gate voltage of each of at least one specified switch of a plurality of switches included in the charging circuitry.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a block diagram illustrating an example configuration of an electronic device and an external electronic device according to various embodiments;

FIG. 3 is a circuit diagram illustrating an example electronic device including a first charging circuit according to various embodiments;

FIG. 4 is a circuit diagram illustrating an example electronic device including a second charging circuit according to various embodiments;

FIG. 5 is a circuit diagram illustrating an example electronic device including a circuit for adjusting a duty ratio of a second charging circuit according to various embodiments;

FIG. 6 is a flowchart illustrating an example operation of controlling battery charging in an electronic device according to various embodiments;

FIG. 7 is a diagram including graphs illustrating current and voltage, when a charging circuit receives power from a programmable power supply (PPS)-supporting external electronic device and operates in a second mode in an electronic device according to various embodiments; and

FIG. 8 is a diagram including graphs illustrating current and voltage, when a control circuit adjusts a gate voltage and duty ratio of at least one switch of a charging circuit in an electronic device according to various embodiments.

### DETAILED DESCRIPTION

An electronic device according to various embodiments will be described in greater detail below with reference to the accompanying drawings. As used in various embodiments, the term user may refer to a person using an electronic device or a device (e.g., an artificial intelligence electronic device) using an electronic device.

The terms used herein are used to describe various example embodiments, and are not intended to limit the scope of the disclosure. Unless the context clearly dictates otherwise, a singular expression may include plural references. All terms used herein, including technical or scientific terms, are intended to have the same meaning as commonly understood by those skilled in the art. Commonly used dictionary-defined terms may be understood to have the same or similar meanings as they have in the context of the relevant art and are not to be construed in an ideal or excessively formal sense unless clearly defined herein. In some instances, even terms defined herein shall not be interpreted to exclude embodiments of the disclosure.

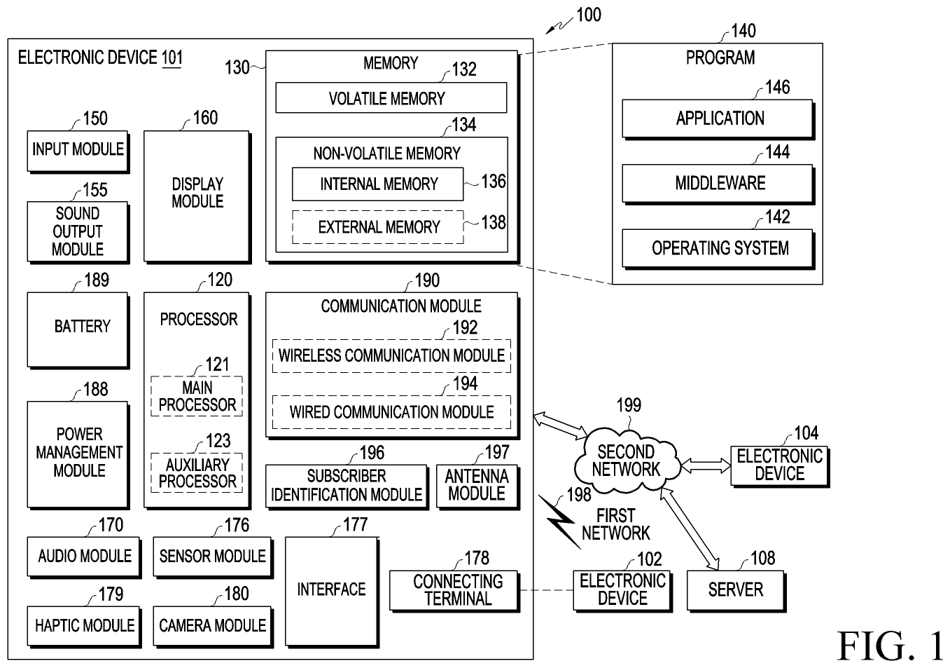

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an ISP or a CP) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the strength of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, ISPs, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to various embodiments, another component (e.g., a radio frequency integrated circuit (RFIC)) other than the radiating element may be additionally formed as part of the antenna module 197.

According to an embodiment, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

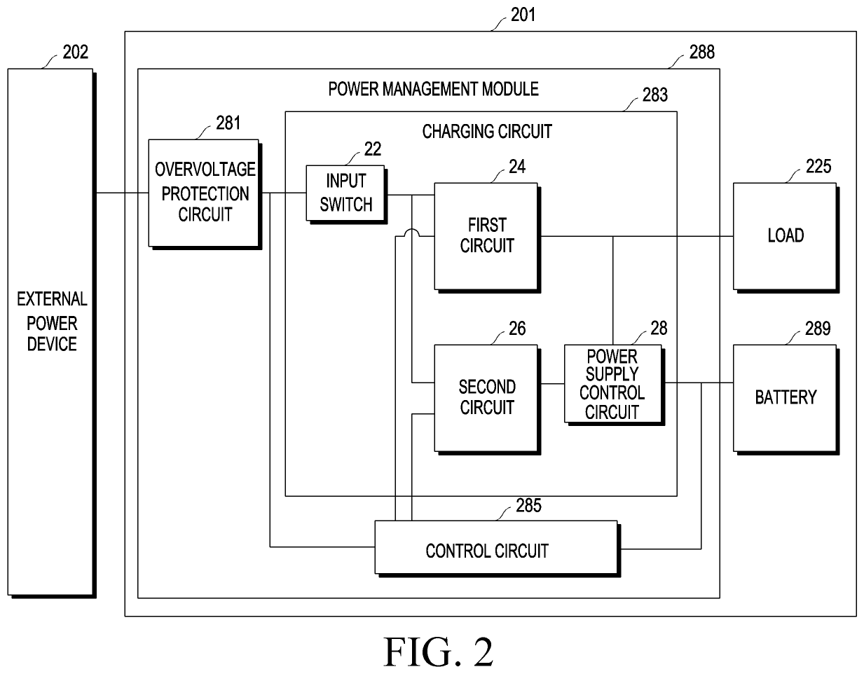

FIG. 2 is a block diagram illustrating an example configuration of an electronic device 201 and an external electronic device 202 according to various embodiments.

Referring to FIG. 2, the electronic device 201 (or power reception device) (e.g., the electronic device 101 in FIG. 1) according to an embodiment may receive power (or a current) from the external electronic device 202 (or external power device or power supply device) (e.g., the electronic device 102 in FIG. 2), while being connected to the external power device 202.

The external electronic device 202 (hereinafter also referred to as external electronic device 202) according to an embodiment may include a fast charging power adapter, a travel adapter (TA), a battery pack, a wireless power transmission device (e.g., wireless charging pad or electronic device), or the like. When the external power device 202 according to an embodiment supports programmable power supply (PPS), it may provide (or transmit) power (or a current) to the electronic device 201 in a direct charging scheme. When the external power device 202 according to an embodiment supports PPS, the external power device 202 according to an embodiment may provide (or transmit) power (or a current) to the electronic device 201, while changing the voltage and/or current of power (or current) provided to the electronic device 201 in each specified charging period (or state) (e.g., in each constant current (CC) or constant voltage (CV) period) based on a charge amount of a battery 289 in the electronic device 201. The external power device 202 according to an embodiment may transmit and receive signals related to charging of the battery 289 through communication (e.g., power delivery (PD)) with the electronic device 201. The external power device 202 according to an embodiment may perform CV or CC control for charging the battery 220, using the PPS function of USB PD 3.0. When the external power device 202 is a device that does not support PPS (e.g., a legacy power adapter), the external power device 202 may provide (or transmit) specified power (or current) to the electronic device 201 without any control based on a charge amount of the battery 289.

The electronic device 201 according to an embodiment may include a power management module (e.g., including various circuitry) 288 (e.g., the power management module 188 in FIG. 1), a load 225 (e.g., a system or at least one module, component, and/or circuit included in the electronic device 101), and the battery 289. The electronic device 201 according to an embodiment may be configured to further include various other components or exclude some of the above components, not limited to the above components. The electronic device 201 according to an embodiment may further include all or a portion (e.g., memory (e.g., the memory 130, the display 160, the communication module (e.g., including communication circuitry) 190, and the processor 120) and/or other components) of the electronic device 101 illustrated in FIG. 1.

The electronic device 201 according to an embodiment may provide power to the load (e.g., a system or at least one module, component, and/or circuit included in the electronic device 201) 225 and charge the battery 289, using power (or current) provided (or received) from the external power device 202 through the power management module 288.

The power management module 288 according to an embodiment may include an overvoltage protection circuit 281, a charging circuit 283, and/or a control circuit (e.g., including various processing and/or control circuitry) 285, and may further include an additional circuit for power management and control in the electronic device 201.

The overvoltage protection circuit (e.g., overvoltage protector (OVP)) 281 according to an embodiment may be connected between the external power device 202 and the charging circuit 283. When power is supplied at a voltage with a specified magnitude or greater from the external power device 202, the Overvoltage protection circuit 281 according to an embodiment may protect the charging circuit 283 by blocking the overvoltage. The overvoltage protection circuit 281 according to an embodiment may be omitted or relocated according to a design change. The overvoltage protection circuit 281 according to an embodiment may be a circuit for protecting an input end to which power is input from the external power device 202.

The charging circuit 283 according to an embodiment may operate differently (or in a different mode) based on whether the external electronic device 202 providing power is a PPS-supporting device or a non-PPS-supporting device.

When the external electronic device 202 is not a PPS-supporting device (e.g., also referred to as a first mode or a non-PPS mode), the charging circuit 283 according to an embodiment may charge the battery 289 and provide power to the load 225, by adjusting power (or a current) input from the external electronic device 202 in each specified charging period (or state) (e.g., in each CC or CV period) based on a charge amount of the battery 289 in the electronic device 201. When the external electronic device 202 is a PPS-supporting device (e.g., also referred to as a second mode or a PPS mode), the charging circuit 283 according to an embodiment may receive power or a current input from the external electronic device 202, which has been adjusted in each specified charging period (or state) (e.g., in each CC or CV period) according to a charge amount of the battery, convert the received power (or current) based on a specified voltage conversion ratio (e.g., about 2:1) or a specified current conversion ratio (e.g., about 1:2), charge the battery 289 with the converted power, and provide the power to the load 225.

The charging circuit 283 according to an embodiment may include an input switch 22, a first circuit 24, a second circuit 26, and/or a power supply control circuit 28. The charging circuit 283 according to an embodiment may further include an additional circuit required for power supply to the load 225 and/or charging power supply to the battery 289.

The input switch 22 according to an embodiment may control power (or a current) input from the external power device 202. The input switch 22 according to an embodiment may operate in an on state to allow input of power (or a current) from the external power device 202, or in an off state to prevent/reduce input of power (or a current) from the external power device 202.

One end of the first circuit 24 according to an embodiment may be connected to the input switch 22. The first circuit 24 according to an embodiment may receive a portion of power (or a current) provided from the external electronic device 202, which has been changed according to a charge amount of the battery 289 by the external electronic device 202, based on the input switch 22 being turned on in the second mode in which the electronic device 201 is connected to the external electronic device 202 supporting PPS. The first circuit 24 according to an embodiment may include a first plurality of switches, convert the input power (or current) based on the specified voltage conversion ratio (e.g., about 2:1) or the specified current conversion ratio (e.g., about 1:2) using the first plurality of switches, and output converted first power (or a first current). A portion or all of the first power (or first current) according to an embodiment may be transmitted to the load 225 and/or the battery 289. When the external electronic device 202 is not a PPS-supporting device (e.g., also referred to as the first mode or the non-PPS mode), the first circuit 24 according to an embodiment may charge the battery 289 and provide power to the load 225, by adjusting power (or a current) input from the external electronic device 202 in each specified charging period (or state) (e.g., in each CC or CV period) based on a charge amount of the battery 289 of the electronic device 201.

One end of the second circuit 26 according to an embodiment may be connected to the input switch 22. The second circuit 26 according to an embodiment may receive another portion of the power or current provided from the external electronic device 202, which has been changed based on the charge amount of the battery 289 by the external electronic device 202, based on the input switch 22 being turned on in the second mode in which the electronic device 201 is connected to the external electronic device 202 supporting PPS. The second circuit 26 according to an embodiment may include a second plurality of switches, convert the input power (or current) based on the specified voltage conversion ratio (e.g., about 2:1) or the specified current conversion ratio (e.g., about 1:2) using the second plurality of switches, and output converted second power (or a second current). A portion or all of the second power (or second current) according to an embodiment may be transmitted to the load 225 and/or the battery 289.

The power supply control circuit 28 according to an embodiment may be connected to an output end of each of the first circuit 24 and the second circuit 26, and may be connected to the load 225 and the battery 289. The power supply control circuit 28 according to an embodiment may transmit a portion or all of the first power and the second power output by the first circuit 24 and the second circuit 26, respectively to the load 225 and/or the battery 289. The power supply control circuit 28 according to an embodiment may include a power supply control switch. The power supply control switch according to an embodiment may supply a portion or all of the first power and the second power output by the first circuit 24 and the second circuit 26, respectively to the battery 289 based on being switched on, or may not supply a portion or any of the first power and the second power output by the first circuit 24 and the second circuit 26, respectively to the battery 289 based on being switched off.

When the external electronic device 202 is a PPS-supporting device, the control circuit 285 according to an embodiment, which may include various control circuitry including, for example, the processor 120 described above, may control the charging circuit 283 to operate in the second mode or identify a state in which the charging circuit 283 is operating in the second mode. The control circuit 285 according to an embodiment may identify that while the charging circuit 283 operates in the second mode, a current transmitted to the load 225 rapidly (or suddenly) decreases below a specified current value, and thus the voltage of the battery 289 is higher than a maximum allowed charging voltage VBAT_LIM (or the current of the battery 289 is higher than a maximum allowed charging current IBAT_LIM). The control circuit 285 according to an embodiment may decrease the voltage of the battery 289 to or below (or below) the maximum allowed charging voltage VBAT_LIM by controlling (or adjusting (e.g., decreasing) a gate voltage of each of at least one specified switch of the first plurality of switches included in the first circuit 24 or the second plurality of switches included in the second circuit 26 and thus adjusting (e.g., increasing) a resistance value, based on the voltage of the battery 289 being higher than the maximum allowed charging voltage VBAT_LIM (or the current of the battery 289 being higher than the maximum allowed charging current IBAT_LIM) while the charging circuit 283 operates in the second mode.

The control circuit 285 according to an embodiment may include various circuitry, including various amplifiers (e.g., at least one error amplifier) and/or may include various processing circuitry (including circuitry described above with respect to the processor 120, which description is equally applicable to the control circuit 285) obtain a value of an input current IIN of the charging circuit, a value of a battery voltage VBAT, and a value of a battery current IBAT, while the charging circuit 283 operates in the second mode. While the charging circuit 283 operates in the second mode, the control circuit 285 according to an embodiment may periodically or continuously sense the value of the input current IIN of the charging circuit 283, the value of the battery voltage VBAT, and the value of the battery current IBAT, or may receive a sensed value of the input current IIN of the charging circuit 283, a sensed value of the battery voltage VBAT, and a sensed value of the battery current IBAT from a separate sensing circuit (not shown). The control circuit 285 according to an embodiment may amplify the differences (or errors) between the value of the input current IIN of the charging circuit 283, the value of the battery voltage VBAT, and the value of the battery current IBAT which have been obtained while the charging circuit 283 operates in the second mode and a specified input current value of the charging circuit, a specified battery voltage value, and a specified battery current value, using respective error amplifiers. The control circuit 285 according to an embodiment may select a smallest error value as a control value (or control output value) using a selection circuit (or a minimum value selection circuit or a min selector) from among the amplified errors of the value of the input current IIN of the charging circuit, the value of the battery voltage VBAT, and the value of the battery current IBAT. For example, when the value of the input current IIN of the charging circuit is greater than an input current limit IIN* to be controlled, the output of an input current error amplifier may be decreased in a negative direction. The selection circuit according to an embodiment may select, as a control value, a value that exceeds a value to be controlled by the largest amount from among the input current value, the battery voltage value, and the battery current value.

The control circuit 285 according to an embodiment may control (or adjust (e.g., decrease)) a resistance value by controlling (or adjusting (e.g., decreasing)) the gate voltage or current of each of at least one specified (or selected) switch of the first plurality of switches included in the first circuit 24 or the second plurality of switches included in the second circuit 26, such that the voltage of the battery 289 is equal to or less than (or less than) the maximum allowed charging voltage VBAT_LIM and/or the current of the battery 289 is equal to or less than (or less than) the maximum allowed charging current IBAT_LIM. According to an embodiment, the control circuit 285 may control the gate voltage of each of the at least one specified switch to be adjusted within a specified gate voltage range (e.g., about 10V (minimum value) to about 20V (maximum value)) (or a specified range of switch resistance values). According to an embodiment, due to the increase of the resistance of the at least one of the first plurality of switches included in the first circuit 24 or the second plurality of switches included in the second circuit 26 in the state where the voltage of the battery 289 is equal to or greater than the maximum allowed charging voltage VBAT_LIM and/or the current of the battery 289 is equal to or greater than the maximum allowed charging current IBAT_LIM, power input to the first circuit 24 and the second circuit 26 may be reduced, and the battery current IBAT and the current input from the external power device 202 may be lowered, thereby preventing/reducing a battery overvoltage state.

According to an embodiment, when the voltage of the battery 289 is not equal to or less than (or less than) the maximum allowed charging voltage VBAT_LIM in the state where the gate voltage of each of the at least one specified switch has been adjusted to the minimum value of the specified gate voltage range, the control circuit 285 may adjust the duty ratio of the first circuit 24 and/or the second circuit 26. For example, the duty ratio may be decreased between a duty ratio of 50% and a specified duty ratio (e.g., 10%) until the voltage of the battery 289 is equal to or less than the maximum allowed charging voltage VBAT_LIM.

An electronic device (e.g., the electronic device 101 in FIG. 1 or the electronic device 201 in FIG. 2) according to an example embodiment may include: a battery (e.g., the battery 189 in FIG. 1 or the battery 289 in FIG. 2), a load (e.g., the load 225 in FIG. 2), charging circuitry (e.g., the charging circuit 283 in FIG. 2), and control circuitry (e.g., the control circuit 285 in FIG. 2). The charging circuitry according to an example embodiment may include: a plurality of switches and be configured to, in a PPS mode, receive power adjusted in each specified charging period according to a charge amount of the battery from an external electronic device, convert a voltage of the received power based on a specified voltage conversion ratio using the plurality of switches, and supply the voltage-converted power to the battery and the load. The control circuitry according to an example embodiment may be configured to: control a gate voltage of at least one specified switch of the plurality of switches, based on a voltage of the battery being higher than a maximum allowed charging voltage or a current of the battery being higher than a maximum allowed charging current during the PPS mode.

The control circuitry according to an example embodiment may be configured to adjust a gate voltage of each of the at least one specified switch within a specified gate voltage range.

The control circuitry according to an example embodiment may be configured to decrease a duty ratio of a capacitive voltage divider included in the charging circuitry, based on the voltage of the battery being higher than the maximum allowed charging voltage or the current of the battery being higher than the maximum allowed charging current in a state where the gate voltage of each of the at least one specified switch is adjusted to a minimum value of the specified gate voltage range.

The control circuitry according to an example embodiment may include: a first error amplifier configured to amplify a difference between an input current value of the charging circuitry obtained based on the charging circuitry operating in the PPS mode and a specified input current value. The control circuitry according to an example embodiment may include a second error amplifier configured to amplify a difference between a battery voltage value obtained based on the charging circuitry operating in the PPS mode and a specified battery voltage value. The control circuitry according to an example embodiment may include a third error amplifier configured to amplify a difference between a battery current value obtained based on the charging circuitry operating in the PPS mode and a specified battery current value. The control circuitry according to an example embodiment may include selection circuitry configured to select a smallest value of the values amplified from the first to third error amplifiers, respectively, as a control value. The control circuitry according to an example embodiment may include gate voltage control circuitry configured to control the gate voltage of the at least one specified switch based on the control value.

The control circuitry according to an example embodiment may further include a fourth error amplifier configured to amplify a difference between the control value output by the selection circuitry and a threshold related to a minimum value of the gate voltage range of the at least one specified switch. The control circuitry according to an example embodiment may further include duty control signal output circuitry configured to decrease a duty ratio of a 2:1 capacitive voltage divider (e.g., cap divider) included in the charging circuitry based on a value output by the fourth error amplifier.

The charging circuitry according to an example embodiment may include a first hybrid charger, wherein the first hybrid charger includes a first plurality of switches including first, second, third and fourth switches, a flying capacitor, and an inductor.

The charging circuitry according to an example embodiment may further include a second hybrid charger, wherein the first hybrid charger is connected in parallel to the first hybrid charger and includes a second plurality of switches including fifth, sixth, seventh and eighth switches, a flying capacitor, and an inductor.

The charging circuitry according to an example embodiment may include a hybrid charger including a first plurality of switches including first, second, third and fourth switches, a flying capacitor, and an inductor, and a 2:1 capacitive voltage divider including a second plurality of switches including fifth, sixth, seventh and eighth switches, and a flying capacitor.

The electronic device according to an example embodiment may further include overvoltage protection circuitry configured to block overvoltage power from being supplied to the charging circuitry from the external electronic device.

The electronic device according to an example embodiment may further include power supply control circuitry configured to supply or not supply a portion or all of power output by the charging circuitry to the load and/or the battery.

The charging circuit 283 of the electronic device 201 according to an embodiment may include a first type of first charging circuit a first charging circuit of a first type (e.g., a 2-phase hybrid charger (first hybrid charger+second hybrid charger)) or a second charging circuit of a second type (e.g., hybrid charger+2:1 capacitive voltage divider). According to an embodiment, when the charging circuit 283 of the electronic device 201 includes the first charging circuit of the first type, the first circuit 24 may include the first hybrid charger, and the second circuit 26 may include the second hybrid charger. According to an embodiment, when the charging circuit 283 of the electronic device 201 includes the second charging circuit of the second type, the first circuit 24 may include the hybrid charger, and the second circuit 26 may include the 2:1 capacitive voltage divider.

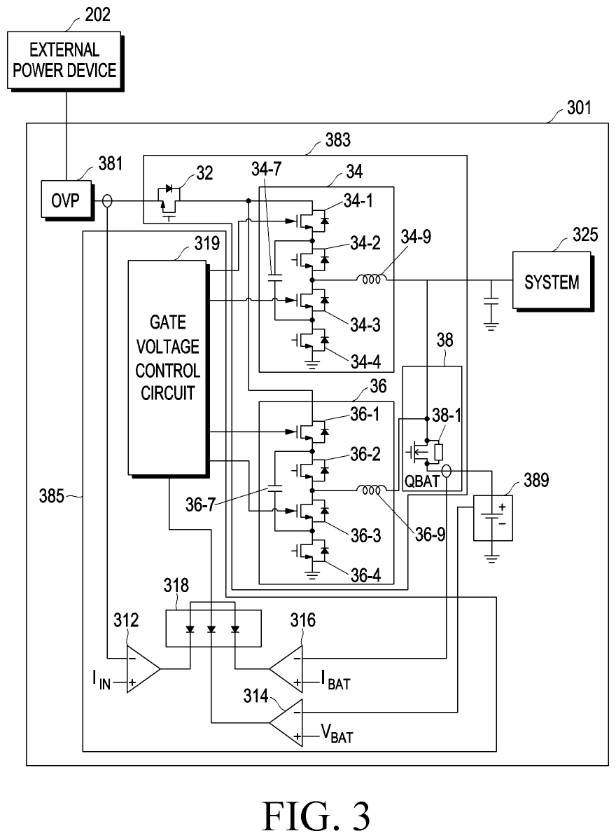

FIG. 3 is a circuit diagram illustrating an example configuration of an electronic device including a first charging circuit according to various embodiments.

Referring to FIG. 3, an electronic device 301 (or power reception device) (e.g., the electronic device 101 in FIG. 1 or the electronic device 201 in FIG. 2) according to an embodiment may receive power (or a current) from the external power device 202 (or power providing device) (e.g., the electronic device 102 in FIG. 2), while being connected to the external power device 202. The electronic device 301 according to an embodiment may further include an OVP 381 (e.g., the overvoltage protection circuit 281 in FIG. 2), a first charging circuit 383 (e.g., the charging circuit 282 in FIG. 2), a control circuit 385 (e.g., the control circuit 285 in FIG. 2), a system 325 (e.g., the load 225 in FIG. 2), and a battery 389 (e.g., the battery 289 in FIG. 2). The electronic device 301 according to an embodiment may further include an additional circuit for power management and power control in the electronic device 301.

When power is supplied at a voltage equal to or greater than a specified magnitude from the external power device 202, the OVP 381 according to an embodiment may protect the first charging circuit 383 by blocking the overvoltage. The OVP 381 according to an embodiment may be omitted or relocated according to a design change. The OVP 381 according to an embodiment may be a circuit for protecting an input end to which power is input from the external power device 202.

The first charging circuit 383 according to an embodiment may operate in the first mode based on the external electronic device 202 providing power being a non-PPS-supporting device, and in the second mode based on the external electronic device 202 being a PPS-supporting device. In the first mode, the first charging circuit 383 according to an embodiment may charge the battery 389 or provide power to the system 325 by adjusting power (or a current) input from the external electronic device 202 in each specified charging period (or state) (e.g., in each CC or CV period) based on a charge amount of the battery 289 of the electronic device 301. In the second mode, the first charging circuit 383 according to an embodiment may charge the battery 389 and provide power to the system 325 by receiving power or a current input from the external electronic device 202, which has been adjusted in each specified charging period (or state) (e.g., in each CC or CV period) based on a charge amount of the battery 289 of the electronic device 301 by the external electronic device 202, and converting the received power (or current) based on a specified voltage conversion ratio (e.g., about 2:1) or a specified current conversion ratio (e.g., about 1:2).

The first charging circuit 383 according to an embodiment may include an input switch 32, a first circuit (also referred to as a ‘first hybrid charger circuit’) 34, a second circuit (also referred to as a ‘second hybrid charger circuit’) 36, and/or a power supply control circuit 38. The first charging circuit 383 according to an embodiment may further include an additional circuit required for power supply to the system 325 and/or charging power supply to the battery 389.

The input switch 32 according to an embodiment may control power (or a current) input from the external power device 202. The input switch 32 according to an embodiment may operate in an on state to allow input of power (or a current) from the external power device 202, or in an off state to prevent/inhibit input of power (or a current) from the external power device 202.

One end of the first hybrid charger circuit 34 according to an embodiment may be connected the input switch 32. The first hybrid charger circuit 34 according to an embodiment may receive a portion (e.g., 50%) of power (or a current) provided by the external electronics 202, which has been changed based on a charge amount of the battery 389, based on the input switch 32 being turned on in the second mode. The first hybrid charger circuit 34 according to an embodiment may include a first plurality of switches 34-1, 34-1, 34-3 and 34-4 (which may be referred to as switches 34-1 to 34-4), and may convert the input power (or current) based on the specified voltage conversion ratio (e.g., about 2:1) or the specified current conversion ratio (e.g., about 1:2) using the first plurality of switches and output converted first power (or first current). A portion or all of the first power (or first current) according to an embodiment may be transmitted to the system 325 and/or the battery 389.

The first hybrid charger circuit 34 according to an embodiment may include the first to fourth switches 34-1 to 34-4, a flying capacitor 34-7, and an inductor 34-9. The first to fourth switches 34-1 to 34-4 according to an embodiment may each include a field effect transistor (FET) (e.g., a metal oxide semiconductor FET (MOSFET) or a quantum FET (QFET)).

The first hybrid charger circuit 34 according to an embodiment may operate by a control signal of a specified frequency having a specified duty ratio (e.g., about 50%). For example, the specified frequency may be set to the same value as a resonant frequency of the flying capacitor 34-7 and the inductor 34-9. The first switch 34-1 and the third switch 34-3 according to an embodiment may operate by a first control signal having a specified duty cycle (e.g., about 50%) in one period, and the second switch 34-2 and the fourth switch 34-4 according to an embodiment may operate by a second control signal having a specified duty cycle (e.g., about 50%) in one period. The second control signal may have a phase opposite to that of the first control signal. According to an embodiment, in a first time period, the first switch 34-1 and the third switch 34-3 may be turned on, and the second switch 34-2 and the fourth switch 34-4 may be turned off. During the first time period, the flying capacitor 34-7 may be charged, and a voltage across the flying capacitor 34-7 may increase. In a second time period following the first time period according to an embodiment, the first switch 34-1 and the third switch 34-3 may be turned off, and the second switch 34-2 and the fourth switch 34-4 may be turned on. During the second time period, the flying capacitor 34-7 may be discharged, the voltage across the flying capacitor 34-7 may decrease, and a current may flow in the inductor 34-9. In the second time period according to an embodiment, the first power may be output from the first hybrid charger circuit 34.

The second hybrid charger circuit 36 according to an embodiment may be connected in parallel to the first hybrid charger circuit 34. The second hybrid charger circuit 36 according to an embodiment may receive another portion (e.g., 50%) of the power (or current) provided by the external electronics 202, which has been changed based on the charge amount of the battery 389, based on the input switch 32 being turned on in the second mode. The second hybrid charger circuit 36 according to an embodiment may include a second plurality of switches 36-1 to 36-4, and may convert the input power (or current) based on the specified voltage conversion ratio (e.g., about 2:1) or the specified current conversion ratio (e.g., about 1:2) using the second plurality of switches and output converted second power (or second current). A portion or all of the second power (or second current) according to an embodiment may be transmitted to the system 325 and/or the battery 389.

The second hybrid charger circuit 36 according to an embodiment may include fifth to eighth switches 36-1, 36-2, 36-3 and 36-4 (which may be referred to as switches 36-1 to 36-4), a flying capacitor 36-7, and an inductor 36-9. The second hybrid charger circuit 36 according to an embodiment may operate by a control signal of a specified frequency having a specified duty ratio (e.g., about 50%). For example, the specified frequency may be set to the same value as a resonant frequency of the flying capacitor 36-7 and the inductor 36-9. The fifth switch 36-1 and the seventh switch 36-3 according to an embodiment may operate by the first control signal having the specified duty cycle (e.g., about 50%) in one period, and the sixth switch 36-2 and the eighth switch 36-4 according to an embodiment may operate by the second control signal having the specified duty cycle (e.g., about 50%) in one period. The second control signal may have a phase opposite to that of the first control signal. In the first time period according to an embodiment, the fifth switch 36-1 and the seventh switch 36-3 may be turned on, and the sixth switch 36-2 and the eighth switch 36-4 may be turned off. During the first time period, the flying capacitor 36-7 may be charged, a voltage across the flying capacitor 36-7 may increase, and a current flowing in the inductor 36-9 may be close to zero. In the first time period according to an embodiment, the second power output from the second hybrid charger circuit 36 may be close to zero. In the second time period following the first time period according to an embodiment, the fifth switch 36-1 and the seventh switch 36-3 may be turned off, and the sixth switch 36-2 and the eighth switch 36-4 may be turned on. During the second time period, the flying capacitor 36-7 may be discharged, the voltage across the flying capacitor 36-7 may decrease, and a current may flow in the inductor 36-9. In the second time period according to an embodiment, the second power may be output from the second hybrid charger circuit 36.

The power supply control circuit 38 according to an embodiment may be connected to an output end of each of the first hybrid charger circuit 34 and the second hybrid charger circuit 36, and connected to the system 325 and the battery 389. The power supply control circuit 38 according to an embodiment may transmit a portion or all of the first power and the second power output by the first hybrid charger circuit 34 and the second hybrid charger circuit 36, respectively to the system 325 and/or the battery 389. The power supply control circuit 38 according to an embodiment may include a power supply control switch 38-1. The power supply control switch 38-1 according to an embodiment may supply a portion or all of the first power and the second power output by the first hybrid charger circuit 34 and the second hybrid charger circuit 36, respectively to the battery 389, based on being switched on, or may not supply a portion or any of the first power and the second power output by the first hybrid charger circuit 34 and the second hybrid charger circuit 36, respectively to the battery 389, based on being switched off.

When the external electronic device 202 is a PPS-supporting device, the control circuit 385 according to an embodiment may control the first charging circuit 383 to operate in the second mode, or identify that the first charging circuit 383 is operating in the second mode. The control circuit 385 according to an embodiment may identify that while the first charging circuit 383 operates in the second mode, a current transmitted to the system 325 rapidly (or suddenly) decreases below a specified current value, and thus the voltage of the battery 389 is higher than above the maximum allowed charging voltage VBAT_LIM or the current of the battery 389 is higher than the maximum allowed charging current IBAT_LIM. Based on the voltage of the battery 389 being higher than the maximum allowed charging voltage VBAT_LIM or the current of the battery 389 being higher than the maximum allowed charging current IBAT_LIM while the first charging circuit 383 operates in the second mode, the control circuit 385 according to an embodiment may adjust (e.g., increase) a resistance value by controlling (or adjusting (e.g., decreasing)) the gate voltage of each of at least one specified (or selected) switch of the first to fourth switches 34-1 to 34-4 or the fifth to eight switches 36-1 to 36-4, such that the voltage of the battery 389 is equal to or less than (or less than) the maximum allowed charging voltage VBAT_LIM and/or the current of the battery 389 is equal to or less than (or less than) the maximum allowed charging current IBAT_LIM. According to an embodiment, the control circuit 385 may adjust (e.g., increase) a resistance value by controlling (or adjusting (e.g., decreasing)) the gate voltage of each of the first switch 34-1, the third switch 34-3, the fifth switch 36-1, and the seventh switch 36-3 among the first to fourth switches 34-1 to 34-4 and the fifth to eight switches 36-1 to 36-4, such that the voltage of the battery 389 is equal to or less than (or less than) the maximum allowed charging voltage VBAT_LIM and/or the current of the battery 389 is equal to or less than (or less than) the maximum allowed charging current IBAT_LIM.

According to an embodiment, a gate voltage circuit 319 may control the gate voltage of the first switch 34-1 and/or the third switch 34-3 to be adjusted (e.g., decreased) during the first time period.

The control circuit 385 according to an embodiment may obtain a value of the input current IIN of the first charging circuit 383, a value of the battery voltage VBAT, and a value of the battery current IBAT, while the first charging circuit 383 operates in the second mode. The control circuit 385 according to an embodiment may periodically or continuously sense the value of the input current IIN of the first charging circuit 383, the value of the battery voltage VBAT, and the value of the battery current IBAT, while the first charging circuit 383 operates in the second mode, or may receive a value of the input current IIN of the first charging circuit 383, a value of the battery voltage VBAT, and a value of the battery current IBAT which have been sensed, from a separate sensing circuit (not shown).

The control circuit 385 according to an embodiment may include a first error amplifier 312, a second error amplifier 314, a third error amplifier 316, a selection circuit 318, and the gate voltage control circuit 319.

The first error amplifier 312 according to an embodiment may amplify a difference (or error) between a specified input current value and the value of the input current IIN of the charging circuit obtained while the first charge circuit 383 is operating in the second mode, and output the amplified difference to the selection circuit 318.

The second error amplifier 314 according to an embodiment may amplify a difference (or error) between a specified battery voltage value and the value of the battery voltage VBAT obtained while the first charging circuit 383 operates in the second mode, and output the amplified difference to the selection circuit 318.

The third error amplifier 316 according to an embodiment may amplify a difference (or error) between a specified battery current value and the value of the battery current IBAT obtained while the first charging circuit 383 operates in the second mode, and output the amplified difference to the selection circuit 318.

The selection circuit 318 (or a minimum value selection circuit or a min selector) according to an embodiment may select the smallest of the values received from the first error amplifier 312, the second error amplifier 314, and the third error amplifier 316 as a control value (or control output value).

The gate voltage control circuit 319 according to an embodiment may adjust (e.g., increase) a resistance value by controlling (or adjusting (e.g., decreasing)) the gate voltage of at least one specified or selected switch (e.g., the first switch 34-1 to 34-4, the third switch 34-3, the fifth switch 36-1, and the seventh switch 36-3) of the first to fourth switches 34-1 to 34-4 or the fifth to eighth switches 36-1 to 36-4 based on the control value selected or output by the selection circuit 318. The gate voltage control circuit 319 according to an embodiment may control the gate voltage of each of the first switch 34-1, the third switch 34-3, the fifth switch 36-1, and the seventh switch 36-3 to a voltage leading to a resistance value for each of the first switch 34-1, the third switch 34-3, the fifth switch 36-1, and the seventh switch 36-3, which makes the voltage of the battery 389 equal to or less than (or less than) the maximum allowed charging voltage VBAT_LIM or the current of the battery 389 equal to or less than (or less than) the maximum allowed charging current IBAT_LIM.

According to an embodiment, the gate voltage control circuit 319 may control the gate voltage of each of the first switch 34-1, the third switch 34-3, the fifth switch 36-1, and the seventh switch 36-3 to be adjusted within a specified gate voltage range. According to an embodiment, because the resistance value of each of the first switch 34-1, the third switch 34-3, the fifth switch 36-1, and the seventh switch 36-3 is increased by adjusting the gate voltage of each of the first switch 34-1, the third switch 34-3, the fifth switch 36-1, and the seventh switch 36-3 in the state where the voltage of the battery 289 is equal to or greater than the maximum allowed charging voltage VBAT_LIM or the current of the battery 289 is equal to or greater than the maximum allowed charging current IBAT_LIM, power input to the first hybrid charger circuit 34 and the second hybrid charger circuit 36 may be reduced, and the battery current IBAT and the current input from the external power device 202 may be decreased, thereby preventing and/or reducing an overcurrent or overvoltage state.

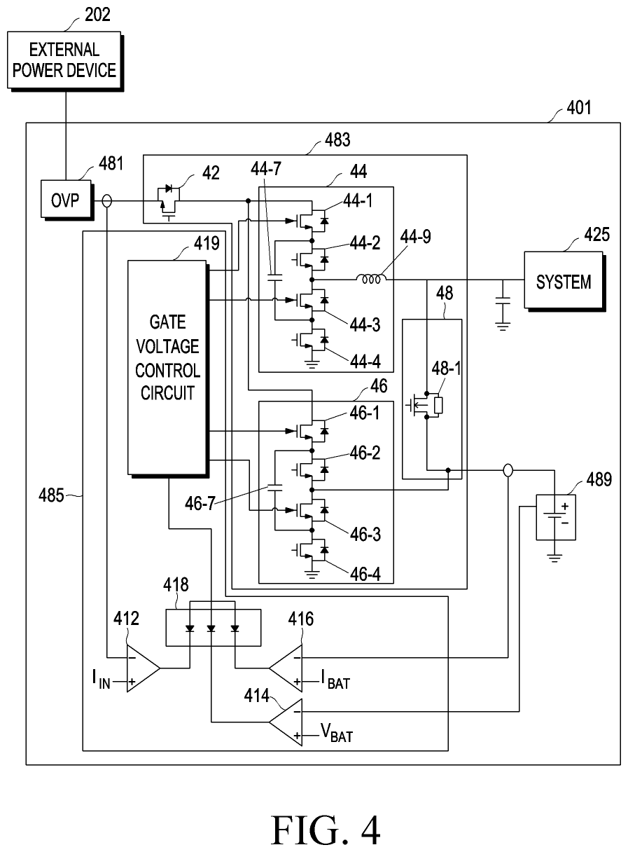

FIG. 4 is a circuit diagram illustrating an example configuration of an electronic device including a second charging circuit according to various embodiments.

Referring to FIG. 4, an electronic device 401 (or power reception device) (e.g., the electronic device 101 in FIG. 1 or the electronic device 201 in FIG. 2) according to an embodiment may receive power (or a current) from the external power device 202 (or power providing device) (e.g., the electronic device 102 in FIG. 2), while being connected to the external power device 202.

The electronic device 401 according to an embodiment may further include an OVP 481 (e.g., the overvoltage protection circuit 281 in FIG. 2), a second charging circuit 483 (e.g., the charging circuit 282 in FIG. 2), a control circuit 485 (e.g., the control circuit 285 in FIG. 2), a system 425 (e.g., the load 225 in FIG. 2), and a battery 489 (e.g., the battery 289 in FIG. 2). The electronic device 401 according to an embodiment may further include an additional circuit for power management and power control in the electronic device 401.

When power is supplied at a voltage equal to or greater than a specified magnitude from the external power device 202, the OVP 481 according to an embodiment may protect the second charging circuit 483 by blocking the overvoltage. The OVP 481 according to an embodiment may be omitted or relocated according to a design change. The OVP 481 according to an embodiment may be a circuit for protecting an input end to which power is input from the external power device 202.

The second charging circuit 483 according to an embodiment may operate in the first mode based on the external electronic device 202 providing power being a non-PPS-supporting device, and in the second mode based on the external electronic device 202 being a PPS-supporting device. In the first mode, the second charging circuit 483 according to an embodiment may charge the battery 489 and provide power to the system 425 by adjusting power (or a current) input from the external electronic device 202 in each specified charging period (or state) (e.g., in each CC or CV period) based on a charge amount of the battery 489 of the electronic device 401. In the second mode, the second charging circuit 483 according to an embodiment may charge the battery 489 and provide power to the system 425 by receiving power or a current input from the external electronic device 202, which has been adjusted in each specified charging period (or state) (e.g., in each CC or CV period) based on a charge amount of the battery 489 by the external electronic device 202, and converting the received power (or current) based on a specified voltage conversion ratio (e.g., about 2:1) or a specified current conversion ratio (e.g., about 1:2).

The second charging circuit 483 according to an embodiment may include an input switch 42, a first circuit (also referred to as a ‘hybrid charger circuit’) 44 (e.g., the first circuit 34 in FIG. 3), a 2:1 capacitive voltage divider 46, and/or a power supply control circuit 48. The second charging circuit 483 according to an embodiment may further include an additional circuit required for power supply to the system 425 and/or charging power supply to the battery 489.

The input switch 42 according to an embodiment may control power (or a current) input from the external power device 202. The input switch 42 according to an embodiment may operate in an on state to allow input of power (or a current) from the external power device 202, or in an off state to prevent or reduce input of power (or a current) from the external power device 202.

The hybrid charger circuit 44 according to an embodiment may have one end connected to the input switch 42 and the other end connected to the power supply control circuit 48. The hybrid charger circuit 44 according to an embodiment may receive a portion (e.g., 50%) of power (or a current) provided by the external electronics 202, which has been changed based on a charge amount of the battery 489, based on the input switch 42 being turned on in the second mode. The hybrid charger circuit 44 according to an embodiment may include a first plurality of switches 44-1, 44-2, 44-3 and 44-4 (which may be referred to as switches 44-1 to 44-4), and may convert the input power (or current) based on a specified voltage conversion ratio (e.g., about 2:1) or a specified current conversion ratio (e.g., about 1:2) using the first plurality of switches and output converted first power (or first current). A portion or all of the first power (or first current) according to an embodiment may be transmitted to the system 425 and/or the battery 489.

The hybrid charger circuit 44 according to an embodiment may include the first to fourth switches 44-1 to 44-4, a flying capacitor 44-7, and an inductor 44-9. The hybrid charger circuit 44 according to an embodiment may operate by a control signal of a specified frequency having a specified duty ratio (e.g., about 50%). For example, the specified frequency may be set to the same value as a resonant frequency of the flying capacitor 44-7 and the inductor 44-9. The first switch 44-1 and the third switch 44-3 according to an embodiment may operate by a first control signal having a specified duty cycle (e.g., about 50%) in one period, and the second switch 44-2 and the fourth switch 44-4 according to an embodiment may operate by a second control signal having a specified duty cycle (e.g., about 50%) in one period. The second control signal may have a phase opposite to that of the first control signal. According to an embodiment, in a first time period, the first switch 44-1 and the third switch 44-3 may be turned on, and the second switch 44-2 and the fourth switch 44-4 may be turned off. During the first time period, the flying capacitor 44-7 may be charged, and a voltage across the flying capacitor 44-7 may increase. In a second time period following the first time period according to an embodiment, the first switch 44-1 and the third switch 44-3 may be turned off, and the second switch 44-2 and the fourth switch 44-4 may be turned on. During the second time period, the flying capacitor 44-7 may be discharged, the voltage across the flying capacitor 44-7 may decrease, and a current may flow in the inductor 34-9. In the second time period according to an embodiment, the first power may be output from the first hybrid charger circuit 44.

The 2:1 capacitive voltage divider 46 according to an embodiment may have one end connected to the input switch 42 and the other end connected to the battery 389. The 2:1 capacitive voltage divider 46 may receive another portion (e.g., 50%) of the power (or current) provided by the external electronics 202, which has been changed based on the charge amount of the battery 489, based on the input switch 42 being turned on in the second mode. The 2:1 capacitive voltage divider 46 according to an embodiment may include a second plurality of switches 46-1, 46-2, 46-3 and 46-4 (which may be referred to as switches 46-1 to 46-4), and may convert the input power (or current) based on the specified voltage conversion ratio (e.g., about 2:1) or the specified current conversion ratio (e.g., about 1:2) using the second plurality of switches and output converted second power (or second current). A portion or all of the second power (or second current) according to an embodiment may be transmitted to the battery 489. The 2:1 capacitive voltage divider 46 according to an embodiment may include fifth to eighth switches 46-1 to 46-4 and a flying capacitor 46-7.

The power supply control circuit 48 according to an embodiment may be connected to the system 425 and the battery 489 between an output end of the hybrid charger circuit 44 and an output end of the 2:1 capacitive voltage divider 46. The power supply control circuit 48 according to an embodiment may transmit a portion or all of the first power and the second power output by the hybrid charger circuit 44 and the 2:1 capacitive voltage divider 46, respectively to the system 425 and/or the battery 489. The power supply control circuit 48 according to an embodiment may include a power supply control switch 48-1. The power supply control switch 48-1 according to an embodiment may supply a portion or all of the first power output by the hybrid charger circuit 44 to the battery 489, based on being switched on, or may not supply a portion or any of the first power output by the hybrid charger circuit 44 to the battery 489, based on being switched off.

When the external electronic device 202 is a PPS-supporting device, the control circuit 485 according to an embodiment may control the second charging circuit 483 to operate in the second mode, or identify that the second charging circuit 483 is operating in the second mode. The control circuit 485 according to an embodiment may identify that while the second charging circuit 483 operates in the second mode, a current transmitted to the system 425 rapidly (or suddenly) decreases below a specified current value, and thus the voltage of the battery 489 is higher than the maximum allowed charging voltage VBAT_LIM or the current of the battery 389 is higher than the maximum allowed charging current IBAT_LIM. Based on the voltage of the battery 489 being higher than the maximum allowed charging voltage VBAT_LIM or the current of the battery 389 being higher than the maximum allowed charging current IBAT_LIM while the second charging circuit 483 operates in the second mode, the control circuit 485 according to an embodiment may adjust (e.g., increase) a resistance value by controlling (or adjusting (e.g., decreasing)) the gate voltage of each of at least one specified (or selected) switch of the first to fourth switches 44-1 to 44-4 or the fifth to eight switches 46-1 to 46-4, such that the voltage of the battery 489 is equal to or less than (or less than) the maximum allowed charging voltage VBAT_LIM and/or the current of the battery 389 is equal to or less than (or less than) the maximum allowed charging current IBAT_LIM. According to an embodiment, the control circuit 485 may adjust (e.g., increase) a resistance value by controlling (or adjusting (e.g., decreasing)) the gate voltage of each of the first switch 44-1, the third switch 44-3, the fifth switch 46-1, and the seventh switch 46-3 among the first to fourth switches 44-1 to 44-4 and the fifth to eight switches 46-1 to 46-4, such that the voltage of the battery 489 is equal to or less than (or less than) the maximum allowed charging voltage VBAT_LIM and/or the current of the battery 389 is equal to or less than (or less than) the maximum allowed charging current IBAT_LIM.

The control circuit 485 according to an embodiment may obtain a value of the input current IIN of the first charging circuit 483, a value of the battery voltage VBAT, and a value of the battery current IBAT, while the second charging circuit 483 operates in the second mode. The control circuit 485 according to an embodiment may periodically or continuously sense the value of the input current IIN of the charging circuit, the value of the battery voltage VBAT, and the value of the battery current IBAT, while the second charging circuit 483 operates in the second mode, or may receive a value of the input current IIN of the first charging circuit, a value of the battery voltage VBAT, and a value of the battery current IBAT which have been sensed, from a separate sensing circuit (not shown).

The control circuit 485 according to an embodiment may include a first error amplifier 412, a second error amplifier 414, a third error amplifier 416, a selection circuit 418, and a gate voltage control circuit 419.

The first error amplifier 412 according to an embodiment may amplify a difference (or error) between a specified input current value and the value of the input current IIN of the charging circuit obtained while the second charging circuit 483 operates in the second mode, and output the amplified difference to the selection circuit 418.

The second error amplifier 414 according to an embodiment may amplify a difference (or error) between a specified battery voltage value and the value of the battery voltage VBAT obtained while the second charging circuit 483 operates in the second mode, and output the amplified difference to the selection circuit 418.

The third error amplifier 416 according to an embodiment may amplify a difference (or error) between a specified battery current value and the value of the battery current IBAT obtained while the second charging circuit 483 operates in the second mode, and output the amplified difference to the selection circuit 418.

The selection circuit 418 (or a minimum value selection circuit or a min selector) according to an embodiment may select the smallest of the values received from the first error amplifier 412, the second error amplifier 414, and the third error amplifier 416 as a control value (or control output value).

The gate voltage control circuit 419 according to an embodiment may adjust (e.g., increase) a resistance value by controlling (or adjusting (e.g., decreasing)) the gate voltage of the at least one specified or selected switch (e.g., the first switch 44-1, the third switch 44-3, the fifth switch 46-1, and the seventh switch 46-3) of the first to fourth switches 44-1 to 44-4 or the fifth to eighth switches 46-1 to 46-4 based on the control value selected or output by the selection circuit 418. The gate voltage control circuit 419 according to an embodiment may control the gate voltage of each of the first switch 44-1, the third switch 44-3, the fifth switch 46-1, and the seventh switch 46-3 to a voltage leading to a resistance value for each of the first switch 44-1, the third switch 44-3, the fifth switch 46-1, and the seventh switch 46-3, which makes the voltage of the battery 489 equal to or less than (or less than) the maximum allowed charging voltage VBAT_LIM or the current of the battery 389 equal to or less than (or less than) the maximum allowed charging current IBAT_LIM.

According to an embodiment, the gate voltage control circuit 419 may control the gate voltage of each of the first switch 44-1, the third switch 44-3, the fifth switch 46-1, and the seventh switch 46-3 to be adjusted within a specified gate voltage range. According to an embodiment, because the resistance value of each of the first switch 44-1, the third switch 44-3, the fifth switch 46-1, and the seventh switch 46-3 is increased by adjusting the gate voltage of each of the first switch 44-1, the third switch 44-3, the fifth switch 46-1, and the seventh switch 46-3 in the state where the voltage of the battery 489 is equal to or greater than the maximum allowed charging voltage VBAT_LIM or the current of the battery 389 is equal to or greater than the maximum allowed charging current IBAT_LIM, power input to the hybrid charger circuit 34 and the 2:1 capacitive voltage divider 46 may be reduced, and the battery current IBAT and the current input from the external power device 202 may be decreased, thereby preventing and/or reducing an overcurrent or overvoltage state.

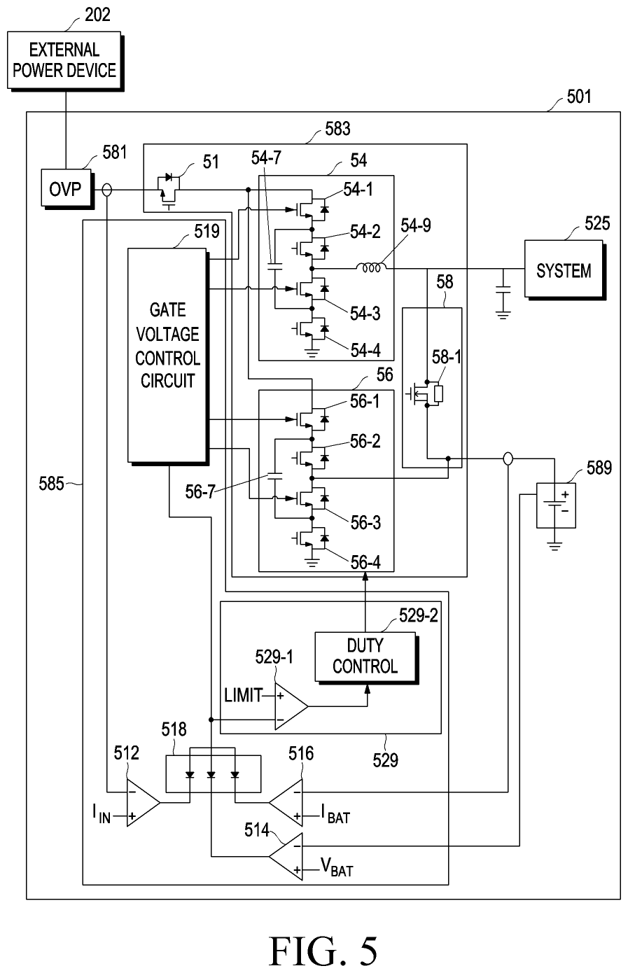

FIG. 5 is a circuit diagram illustrating an example configuration of an electronic device including a circuit for adjusting the duty cycle of a second charging circuit according to various embodiments.

Referring to FIG. 5, an electronic device 501 (or power reception device) (e.g., the electronic device 101 in FIG. 1 or the electronic device 201 in FIG. 2) according to an embodiment may receive power (or a current) from the external power device 202 (or a power providing device) (e.g., the electronic device 102 in FIG. 2), while being connected to the external power device 202.

The electronic device 501 according to an embodiment may include an OVP 581 (e.g., the overvoltage protection circuit 281 in FIG. 2), a second charging circuit 583 (e.g., the charging circuit 282 in FIG. 2), a control circuit 585 (e.g., the control circuit 285 in FIG. 2), a system 525 (e.g., the load 225 in FIG. 2), and a battery 589 (e.g., the battery 289 in FIG. 2). The electronic device 501 according to an embodiment may be an electronic device which further includes a component (e.g., a duty ratio controller 529) controlling a duty cycle of a 2:1 capacitive voltage divider 56 in the second charging circuit 583 in addition to the electronic device 401 in FIG. 4.

The second charging circuit 583 according to an embodiment may include an input switch 51, a first circuit (also referred to as a ‘hybrid charger circuit’) 54 (e.g., the first circuit 34 in FIG. 3 or the first circuit 44 in FIG. 4), a 2:1 capacitive voltage divider 56, and/or a power supply control circuit 58. The first circuit 54 according to an embodiment may include the first to fourth switches 54-1 to 54-4, a flying capacitor 54-7, and an inductor 54-9. The 2:1 capacitive voltage divider 56 according to an embodiment may include fifth to eighth switches 56-1 to 56-4 and a flying capacitor 56-7. The power supply control circuit 548 according to an embodiment may include a power supply control switch 58-1.

The configurations and operations of the OVP 581, the second charging circuit 583, the system 525, and the battery 589 of the electronic device 501 according to an embodiment are the same as or similar to those of the OVP 481, the second charging circuit 483, the system 425, and the battery 489 in FIG. 4, and thus their description will be avoided herein.

When the voltage of the battery 589 is not equal to or less than (or less than) the maximum allowed charging voltage VBAT_LIM or the current of the battery 589 is not equal to or less than (or less than) the maximum allowed charging current IBAT_LIM in the state where the gate voltage of each of a first switch 54-1, a third switch 54-3, a fifth switch 56-1, and a seventh switch 56-3 has been adjusted to a minimum value (e.g., about 10V) of a specified gate voltage range (e.g., about 10V (minimum value) to about 20V (maximum value)) through the duty ratio controller 529, the control circuit 585 in the electronic device 501 according to an embodiment may decrease a duty ratio of the 2:1 capacitive voltage divider 56 to between 50% and a specified duty ratio (e.g., 10%), such that the voltage of the battery 589 is equal to or less than (or less than) the maximum allowed charging voltage VBAT_LIM or the current of the battery 589 is equal to or less than (or less than) the maximum allowed charging current IBAT_LIM.

The duty ratio controller 529 according to an embodiment may include a fourth error amplifier 529-1 and a duty control signal outputter 529-2.

The fourth error amplifier 529-1 according to an embodiment may amplify a difference (or error) between a control value output by the selection circuit 518 and a threshold (limit) (e.g., a value that adjusts a gate voltage to the minimum value (e.g., about 10V)) and output the amplified difference to the duty control signal outputter 529-2. According to an embodiment, the duty ratio controller 529 may be included in a gate voltage control circuit 519. According to an embodiment, the duty control signal may be generated by the duty control signal outputter 592-2 included in the gate voltage control circuit 519 based on a signal from the selection circuit 518. The gate voltage control circuit 519 may adjust the duty ratio of an input of a switch gate based on the signal from the selection circuit 518.

The duty control signal outputter 529-2 according to an embodiment may decrease the duty ratio of the 2:1 capacitive voltage divider 56 to between 50% and the specified duty ratio (e.g., 10%) based on the value output by the fourth error amplifier 529-1, such that the voltage of the battery 589 is equal to or less than the maximum allowed charging voltage VBAT_LIM.

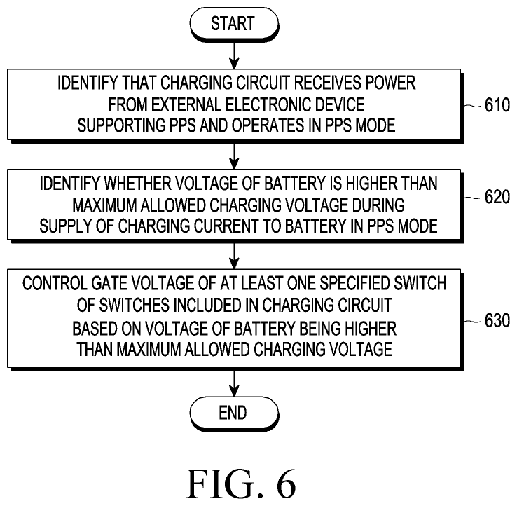

FIG. 6 is a flowchart illustrating an example method of controlling battery charging in an electronic device according to various embodiments.

Referring to FIG. 6, a control circuit (e.g., the processor 120 or the power management module 188 in FIG. 1, the power management module 288 or the control circuit 285 in FIG. 2, the control circuit 385 in FIG. 3, the control circuit 485 in FIG. 4, or the control circuit 585 in FIG. 5 (the following description is given in the context of the control circuit 585 in FIG. 5 as an example) may perform at least one of operations 610 to 630.

In operation 610, the control circuit 585 according to an embodiment may receive power from the external electronic device 202 supporting PPS, and identify that the charging circuit (e.g., the second charging circuit 583) is operating in the second mode (or PPS charging mode).

In operation 620, the control circuit 585 according to an embodiment may identify that a current transmitted to the system 525 rapidly (or suddenly) decreases below a specified current value, and thus the voltage of the battery 589 becomes (rapidly) higher (greater) than the maximum allowed charging voltage VBAT_LIM (or the current of the battery 589 becomes (rapidly) higher (greater) than the maximum allowed charging current IBAT_LIM) during supply of a charging current to the battery 589 in the second mode.

In operation 630, the control circuit 585 according to an embodiment may adjust (e.g., increase) a resistance value by controlling (or adjusting (e.g., decreasing)) the gate voltage of each of at least one specified (or selected) switch of the switches included in the second charging circuit 583, based on the voltage of the battery 589 becoming greater than the maximum allowed charging voltage VBAT_LIM (or the current of the battery 589 becoming greater than the maximum allowed charging current IBAT_LIM) during the supply of the charging current to the battery 589 in the second mode. Based on the voltage of the battery 489 (rapidly) being higher than the maximum allowed charging voltage VBAT_LIM (or the current of the battery 489 (rapidly) being higher than the maximum allowed charging current IBAT_LIM) during the supply of the charging current to the battery 589 in the second mode, the control circuit 585 according to an embodiment may adjust (e.g., increase) a resistance value by controlling (or adjusting (e.g., decreasing)) the gate voltage of each of the first switch 54-1, the third switch 54-3, the fifth switch 56-1, and the eighth switch 56-4 among the first to fourth switches 54-1, 54-2, 54-3 and 54-4 (which may be referred to as switches 54-1 to 54-4) and the fifth to eighth switches 56-1, 56-2, 56-3 and 56-4 (which may referred to as switches 56-1 to 56-4), such that the voltage of the battery 589 is equal to or less than (or less than) the maximum allowed charging voltage VBAT_LIM (or the current of the battery 489 is equal to or less than (or less than) the maximum allowed charging current IBAT_LIM).

When the voltage of the battery 589 is not equal to or less than (or less than) the maximum allowed charging voltage VBAT_LIM in the state where the gate voltage of the at least one switch included in the second charging circuit 583 has been adjusted to a specified gate voltage range, the control circuit 585 according to an embodiment may further control to decrease the duty ratio of the 2:1 capacitive voltage divider 56 included in the second charging circuit 583 to a duty ratio between 50% and a specified duty ratio, (e.g., 10%), which makes the voltage of the battery 589 equal to or less than the maximum allowed charging voltage VBAT_LIM (or the current of the battery 589 equal to or less than the maximum allowed charging current IBAT_LIM).

A method for controlling charging of a battery in an electronic device (e.g., 101 in FIG. 1, 201 in FIG. 2, 301 in FIG. 3, 401 in FIG. 4, or 501 in FIG. 5) including a battery (e.g., 189 in FIG. 1, 289 in FIG. 2, 389 in FIG. 3, 489 in FIG. 4, or 589 in FIG. 5), a load (e.g., 225 in FIG. 2, 325 in FIG. 3, 425 in FIG. 4, or 525 in FIG. 5), charging circuitry (e.g., 283 in FIG. 2, 383 in FIG. 3, 483 in FIG. 4, or 583 in FIG. 5), and control circuitry (e.g., 285 in FIG. 2, 385 in FIG. 3, 485 in FIG. 4, or 585 in FIG. 5) according to an example embodiment may include: identifying, through the control circuitry, that the charging circuitry supplies a charging current to the battery by receiving power from an external electronic device supporting PPS in a PPS mode; identifying, through the control circuitry, whether a voltage of the battery is higher than a maximum allowed charging voltage or a current of the battery is higher than a maximum allowed charging current during supply of the charging current to the battery in the PPS mode; based on the voltage of the battery being higher than the maximum allowed charging voltage or the current of the battery being higher than the maximum allowed charging current, controlling, through the control circuitry, a gate voltage of each of at least one specified switch of a plurality of switches included in the charging circuitry.

In the method according to an example embodiment, the gate voltage of each of the at least one specified switch may be adjusted within a specified gate voltage range.

The method according to an example embodiment may further include: decreasing a duty ratio of a capacitive voltage divider included in the charging circuitry, based on the voltage of the battery being higher than the maximum allowed charging voltage or the current of the battery being higher than the maximum allowed charging current in a state where the gate voltage of each of the at least one specified switch is adjusted to a minimum value of the specified gate voltage range.

The method according to an example embodiment may include: amplifying, by the control circuitry through a first error amplifier, a difference between an input current value of the charging circuitry obtained based on the charging circuitry operating in the PPS mode and a specified input current value; amplifying, by the control circuitry through a second error amplifier, a difference between a battery voltage value obtained based on the charging circuitry operating in the PPS mode and a specified battery voltage value; amplifying, by the control circuitry through a third error amplifier, a difference between a battery current value obtained based on the charging circuitry operating in the PPS mode and a specified battery current value; selecting, by the control circuitry, a smallest value of values amplified from the first to third error amplifiers, respectively as a control value; and controlling, by the control circuitry, the gate voltage of the at least one specified switch based on the control value.

The method according to an example embodiment may further include amplifying, by the control circuitry through a fourth error amplifier, a difference between the selected control value and a threshold related to the minimum value of the gate voltage range of the at least one specified switch; and decreasing a duty ratio of a 2:1 capacitive voltage divider included in the charging circuitry based on the difference amplified from the fourth error amplifier.

In the method according to an example embodiment, the charging circuitry may include a first hybrid charger including a first plurality of switches including first, second, third and fourth switches, a flying capacitor, and an inductor, and a second hybrid charger connected in parallel to the first hybrid charger and including a second plurality of switches including fifth, sixth, seventh and eighth switches, a flying capacitor, and an inductor.

In the method according to an example embodiment, the charging circuitry may include a hybrid charger including a first plurality of switches including first, second, third and fourth switches, a flying capacitor, and an inductor, and a 2:1 capacitive voltage divider including a second plurality of switches including fifth, sixth, seventh, and eighth switches, and a flying capacitor.

The method according to an example embodiment may further include blocking overvoltage power from being supplied to the charging circuitry from the external electronic device by an overvoltage protection circuit of the electronic device.

The method according to an example embodiment may further include controlling, by power supply control circuitry of the electronic device, whether to supply or not supply a portion or all of power output by the charging circuit to the load and/or the battery.

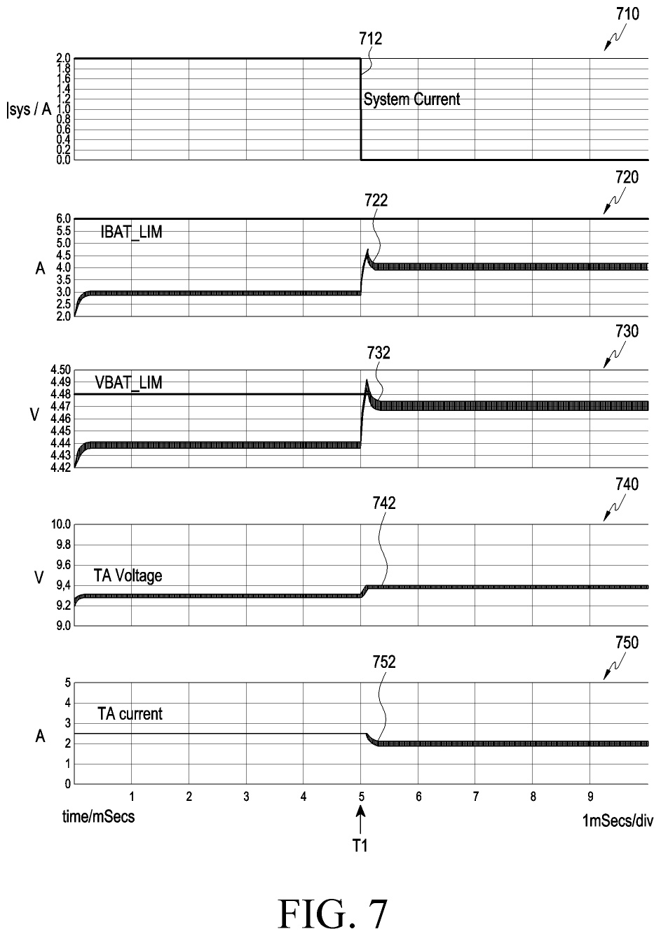

FIG. 7 is a diagram illustrating including graphs illustrating current and voltage, when a charging circuit operates in a second mode by receiving power from an external electronic device supporting PPS in an electronic device according to various embodiments.

Referring to FIG. 7, in a first graph 710 according to an embodiment, a horizontal axis may represent time (ms), and a vertical axis may represent current (A). A first waveform 712 of the first graph 710 may represent a current lsys/A flowing in a system (e.g., the load 225 in FIG. 2, the system 325 in FIG. 3, the system 425 in FIG. 4, or the system 525 in FIG. 5) (hereinafter, the system 525 in FIG. 5 is taken as an example, for description) of an electronic device (e.g., the electronic device 101 in FIG. 1, the electronic device 201 in FIG. 2, the electronic device 301 in FIG. 3, the electronic device 401 in FIG. 4, or the electronic device 501 in FIG. 5) (hereinafter, the electronic device 501 in FIG. 5 is taken as an example, for description). In a second graph 720 according to an embodiment, a horizontal axis may represent time (ms), and a vertical axis may represent current (A). A second waveform 722 of the second graph 720 may represent a charging current for a battery (e.g., the battery 289 in FIG. 2, the battery 389 in FIG. 3, the battery 489 in FIG. 4, or the battery 589 in FIG. 5) (hereinafter, the battery 589 is taken as an example, for description). In a third graph 730 according to an embodiment, a horizontal axis may represent time (ms), and a vertical axis may represent voltage (V). A third waveform 732 of the third graph 730 may represent a charging voltage for the battery 589. In a fourth graph 740 according to an embodiment, a horizontal axis may represent time (ms), and a vertical axis may represent voltages (V). A fourth waveform 742 of the fourth graph 740 may represent the TA voltage of power provided from the external power device 202. In a fifth graph 750 according to an embodiment, a horizontal axis may represent time (ms), and a vertical axis may represent current (A). A fifth waveform 752 of the fifth graph 750 may represent TA current of power provided from the external power device 202.

Referring to the first graph 710 according to an embodiment, when the charging circuit (e.g., the charging circuit 283 in FIG. 2, the first charging circuit 383 in FIG. 3, the second charging circuit 483 in FIG. 4, or the second charging circuit 583 in FIG. 5) (hereinafter, the second charging circuit 583 is taken as an example, for description) operates in the second mode, the system current 712 flowing in the system 525 may change rapidly (e.g., a transient state). For example, when the charging circuit 583 operates in the second mode, the system current 712 may rapidly (or suddenly) fall from 2 A to 0 A. Referring to the third graph 730 according to an embodiment, when the system current 712 is 2 A (e.g., until before T1), the battery voltage VBAT of the battery 589 may be lower than the maximum allowed charging voltage VBAT_LIM, and thus the voltage (TA voltage) and current (TA current) of the external power supply 202 may be maintained to be a specified voltage (e.g., about 9.3V) and a specified current (e.g., about 2.5 A). According to an embodiment, when the system current 712 rapidly falls from 2 A to 0 A, such as at time T1, the current flowing in the battery 589 may increase rapidly, and the battery voltage VBAT 732 may be higher than the maximum allowed charging voltage VBAT_LIM (e.g., about 4.48V) after time T1. According to an embodiment, when the charging circuit 583 operates in the second mode, a problem may occur in case that an overvoltage state in which the battery voltage VBAT is higher than the maximum allowed charging voltage VBAT_LIM lasts for several ms after time T1 until before the external power device 202 reduces the voltage according to a PPS algorithm.

When the battery voltage VBAT is higher than the maximum allowed charging voltage VBAT_LIM (e.g., about 4.48V) due to the rapid decrease of the system current 712 from 2 A to 0 A, such as at time T1, the control circuit 586 of the electronic device 501 according to an embodiment may control (e.g., increase) a resistance value by controlling (or adjusting (e.g., decreasing)) the gate voltage of each of at least one specified (or selected) switch of the switches included in the second charging circuit 583, to ensure that the voltage of the battery 589 does not exceed the maximum allowed charging voltage VBAT_LIM.

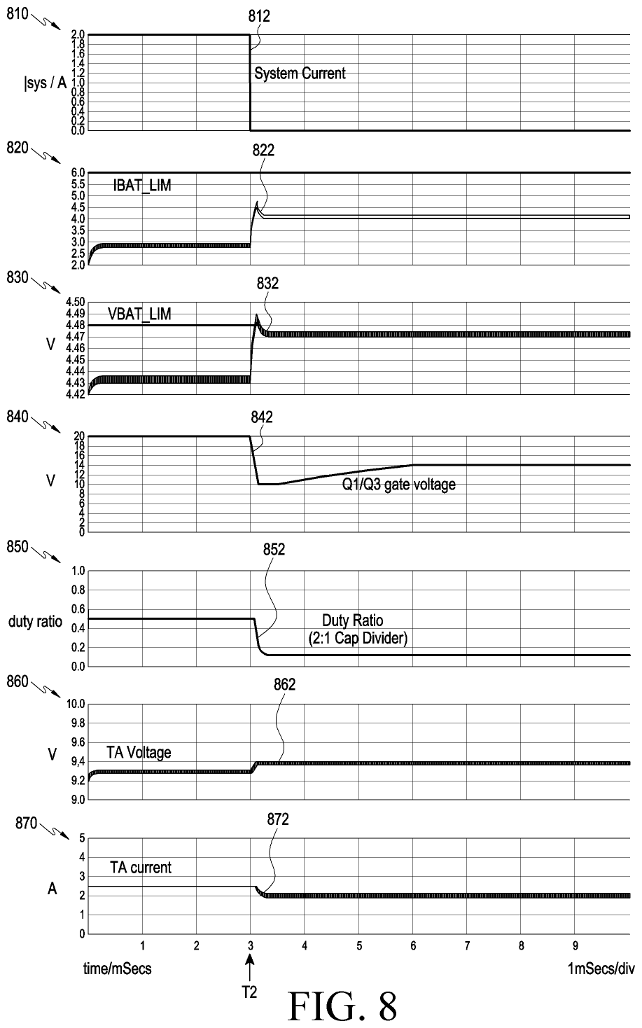

FIG. 8 is a diagram illustrating including graphs illustrating current and voltage, when a charging circuit adjusts the gate voltage and duty ratio of at least one switch of a charging circuit in an electronic device according to various embodiments.

Referring to FIG. 8, in a sixth graph 810 according to an embodiment, a horizontal axis may represent time (ms), and a vertical axis may represent current (A). A sixth waveform 812 of the sixth graph 810 may represent current lsys/A flowing in a system (e.g., the load 225 in FIG. 2, the system 325 in FIG. 3, the system 425 in FIG. 4, or the system 525 in FIG. 5) (hereinafter, the system 525 is taken as an example, for description) of an electronic device (e.g., the electronic device 101 in FIG. 1, the electronic device 201 in FIG. 2, the electronic device 301 in FIG. 3, the electronic device 401 in FIG. 4, or the electronic device 501 in FIG. 5) (hereinafter, the electronic device 501 in FIG. 5 is taken as an example, for description). In a seventh graph 820 according to an embodiment, a horizontal axis may represent time (ms), and a vertical axis may represent current (A). A seventh waveform 822 of the seventh graph 820 may represent a charging current for a battery (e.g., the battery 289 in FIG. 2, the battery 389 in FIG. 3, the battery 489 in FIG. 4, or the battery 589 in FIG. 5) (hereinafter, the battery 589 is taken as an example, for description). In an eighth graph 830 according to an embodiment, a horizontal axis may represent time (ms), and a vertical axis may represent voltage (V). An eighth waveform 832 of the eighth graph 830 may represent a charging voltage for the battery 589. In a ninth graph 840 according to an embodiment, a horizontal axis may represent time (ms), and a vertical axis may represent voltage (V). A ninth waveform 842 of the ninth graph 840 may represent a gate voltage. In a tenth graph 850 according to an embodiment, a horizontal axis may represent time (ms), and a vertical axis may represent a duty ratio. A tenth waveform 852 of the tenth graph 850 may represent the duty ratio of the 2:1 capacitive voltage divider 56. In an eleventh graph 860 according to an embodiment, a horizontal axis may represent time (ms), and a vertical axis may represent voltage (V). An eleventh waveform 862 of the eleventh graph 860 may represent a voltage (TA voltage) of power provided from the external power device 202. In a twelfth graph 870 according to an embodiment, a horizontal axis may represent time (ms), and a vertical axis may represent current (A). A twelfth waveform 872 of the twelfth graph 870 may represent the current (TA current) of power provided from the external power device 202.

Referring to the sixth graph 810 according to an embodiment, when the battery voltage VBAT is higher than the maximum allowed charging voltage VBAT_LIM (e.g., about 4.48V) due to a rapid decrease of the system current 812 from 2 A to 0 A, such as at time T2, the control circuit 586 of the electronic device 501 may adjust the gate voltage of at least one switch included in the second charging circuit 583 to the minimum value (e.g., about 10V) of a specified gate voltage range (e.g., about 10V (minimum set value) to about 20V (maximum set value)). although this may temporarily stabilize the battery voltage VBAT, when the voltage of the battery 589 does not decrease to or below (or below) the maximum allowed charging voltage VBAT_LIM even with the gate voltage of the at least one switch adjusted to the minimum value of the specified gate voltage range (842), the control circuit 586 according to an embodiment may decrease the duty ratio of the 2:1 capacitive voltage divider 56 to a duty ratio (e.g., 20%) between 50% and a specified duty ratio (e.g., 10%), such that the voltage of the battery 589 is maintained to be equal to or lower than the maximum allowed charging voltage VBAT_LIM (852). When the voltage or current of the battery 589 decreases after the voltage of the battery 589 is adjusted not to exceed the maximum allowed charging voltage VBAT_LIM, the control circuit 586 according to an embodiment may increase the voltages of the first switch 54-1 and the third switch 54-3 and increase the duty ratio, or increase the duty ratio and increase the voltages of the first switch 54-1 and the third switch 54-3, in order to increase the current or voltage again.

The electronic device according to an embodiment of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), the element may be coupled with the other element directly (e.g., wiredly), wirelessly, or via a third element.

As used in connection with an embodiment of the disclosure, the term “module” may include a unit implemented in hardware, software, or firmware, or any combination thereof, and may interchangeably be used with other terms, for example, logic, logic block, part, or circuitry. A module may be a single integral component, or a minimum unit or part thereof, adapted to perform one or more functions. For example according to an embodiment the module may be implemented in a form of an application-specific integrated circuit (ASIC).

Embodiments of the disclosure may be implemented as software (e.g., the program 140) including one or more instructions that are stored in a storage medium (e.g., the internal memory 136 or the external memory 138) that is readable by a machine (e.g., the electronic device 101). For example, a processor (e.g., the 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment of the disclosure, in a non-transitory storage medium storing instructions, the instructions may be configured to, when executed by an electronic device, cause the electronic device to perform at least one operation, and the at least one operation may include: identifying, through control circuitry, that charging circuitry supplies a charging current to the battery by receiving power from an external electronic device supporting PPS in a PPS mode, identifying, through control circuitry, whether a voltage of a battery is higher than a maximum allowed charging voltage during supply of the charging current to the battery in the PPS mode, and based on the voltage of the battery being higher than the maximum allowed charging voltage or a current of the battery being higher than a maximum allowed charging current, controlling, through control circuitry, a gate voltage of each of at least one specified switch of a plurality of switches included in the charging circuitry.

According to an embodiment, each component (e.g., a module or a program) of the above-described components may include a single entity or multiple entities, and some of the multiple entities may be separately disposed in different components. According to an embodiment, one or more of the above-described components may be omitted, or one or more other components may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
a battery;
a load;
charging circuitry; and
control circuitry,
wherein the charging circuitry includes a plurality of switches, and is configured to, in a programmable power supply (PPS) mode, receive power adjusted in each specified charging period according to a charge amount of the battery from an external electronic device, convert a voltage of the received power based on a specified voltage conversion ratio using the plurality of switches, and supply the voltage-converted power to the battery and the load, and
wherein the control circuitry comprises at least one amplifier and is configured to control a gate voltage of at least one specified switch of the plurality of switches, based on a voltage of the battery being higher than a maximum allowed charging voltage or a current of the battery being higher than a maximum allowed charging current during the PPS mode.

2. The electronic device of claim 1, wherein the control circuitry is configured to adjust a gate voltage of each of the at least one specified switch within a specified gate voltage range.

3. The electronic device of claim 1, wherein the control circuitry is configured to decrease a duty ratio of a capacitive voltage divider included in the charging circuitry, based on the voltage of the battery being higher than the maximum allowed charging voltage or the current of the battery being higher than the maximum allowed charging current in a state where the gate voltage of each of the at least one specified switch is adjusted to a minimum value of the specified gate voltage range.

4. The electronic device of claim 1, wherein the control circuitry includes:
a first error amplifier configured to amplify a difference between an input current value of the charging circuitry obtained based on the charging circuitry operating in the PPS mode and a specified input current value;
a second error amplifier configured to amplify a difference between a battery voltage value obtained based on the charging circuitry operating in the PPS mode and a specified battery voltage value;
a third error amplifier configured to amplify a difference between a battery current value obtained based on the charging circuitry operating in the PPS mode and a specified battery current value;
selection circuitry configured to select a smallest value of the values amplified from the first, second and third error amplifiers, respectively, as a control value; and
gate voltage control circuitry configured to control the gate voltage of the at least one specified switch based on the control value.

5. The electronic device of claim 4, wherein the control circuitry further includes:
a fourth error amplifier configured to amplify a difference between the control value output by the selection circuitry and a threshold related to the minimum value of the gate voltage range of the at least one specified switch; and
duty control signal output circuitry configured to decrease a duty ratio of a 2:1 capacitive voltage divider included in the charging circuitry based on a value output by the fourth error amplifier.

6. The electronic device of claim 1, wherein the charging circuitry includes a first hybrid charger,
wherein the first hybrid charger includes a first plurality of switches including first, second, third and fourth switches, a flying capacitor, and an inductor.

7. The electronic device of claim 1, wherein the charging circuitry further includes a second hybrid charger,
wherein the second hybrid charger is connected in parallel to the first hybrid charger and includes a second plurality of switches including fifth, sixth, seventh and eighth switches, a flying capacitor, and an inductor.

8. The electronic device of claim 1, wherein the charging circuitry includes:
a hybrid charger including a first plurality of switches including first, second, third and fourth switches, a flying capacitor, and an inductor; and
a 2:1 capacitive voltage divider including a second plurality of switches including fifth, sixth, seventh and eighth switches, and a flying capacitor.

9. The electronic device of claim 1, further comprising overvoltage protection circuitry configured to block overvoltage power from being supplied to the charging circuitry from the external electronic device.

10. The electronic device of claim 1, further comprising power supply control circuitry configured to supply or not supply a portion or all of power output by the charging circuitry to the load and/or the battery.

11. A method of controlling charging of a battery in an electronic device including: a battery, a load, charging circuitry, and control circuitry, the method comprising:
identifying, through the control circuitry, that the charging circuitry supplies a charging current to the battery by receiving power from an external electronic device supporting programmable power supply (PPS) in a PPS mode;
identifying, through the control circuitry, whether a voltage of the battery is higher than a maximum allowed charging voltage or a current of the battery is higher than a maximum allowed charging current during supply of the charging current to the battery in the PPS mode; and
based on the voltage of the battery being higher than the maximum allowed charging voltage or the current of the battery being higher than the maximum allowed charging current, controlling, through the control circuitry, a gate voltage of each of at least one specified switch of a plurality of switches included in the charging circuitry.

12. The method of claim 11, wherein the gate voltage of each of the at least one specified switch is adjusted within a specified gate voltage range.

13. The method of claim 11, further comprising decreasing a duty ratio of a capacitive voltage divider included in the charging circuitry, based on the voltage of the battery being higher than the maximum allowed charging voltage or the current of the battery being higher than the maximum allowed charging current in a state where the gate voltage of each of the at least one specified switch is adjusted to a minimum value of the specified gate voltage range.

14. The method of claim 11, further comprising:
amplifying, by the control circuitry through a first error amplifier, a difference between an input current value of the charging circuitry obtained based on the charging circuitry operating in the PPS mode and a specified input current value;
amplifying, by the control circuitry through a second error amplifier, a difference between a battery voltage value obtained based on the charging circuitry operating in the PPS mode and a specified battery voltage value by the charging circuitry;
amplifying, by the control circuitry through a third error amplifier, a difference between a battery current value obtained based on the charging circuitry operating in the PPS mode and a specified battery current value by the charging circuitry;
selecting, by the control circuitry, a smallest value of values amplified from the first, second and third error amplifiers, respectively as a control value; and
controlling, by the control circuitry, the gate voltage of the at least one specified switch based on the control value.

15. The method of claim 14, further comprising:
amplifying, by the control circuitry through a fourth error amplifier, a difference between the selected control value and a threshold related to the minimum value of the gate voltage range of the at least one specified switch; and
decreasing a duty ratio of a 2:1 capacitive voltage divider included in the charging circuitry based on the difference amplified from the fourth error amplifier.

16. The method of claim 11, wherein the charging circuitry includes:
a first hybrid charger including a first plurality of switches including first, second, third and fourth switches, a flying capacitor, and an inductor; and
a second hybrid charger connected in parallel to the first hybrid charger and including a second plurality of switches including fifth, sixth, seventh and eighth switches, a flying capacitor, and an inductor.

17. The method of claim 11, wherein the charging circuitry includes:
a hybrid charger including a first plurality of switches including first, second, third and fourth switches, a flying capacitor, and an inductor; and
a 2:1 capacitive voltage divider including a second plurality of switches including fifth, sixth, seventh and eighth switches, and a flying capacitor.

18. The method of claim 11, further comprising blocking overvoltage power from being supplied to the charging circuitry from the external electronic device by overvoltage protection circuitry of the electronic device.

19. The method of claim 11, further comprising controlling, by power supply control circuitry of the electronic device, to supply or to not supply a portion or all of power output by the charging circuitry to the load and/or the battery.

20. A non-transitory computer-readable storage medium storing instructions which, when executed by an electronic device, cause the electronic device to perform at least one operation, comprising:
identifying, through control circuitry, that a charging circuitry supplies a charging current to the battery by receiving power from an external electronic device supporting programmable power supply (PPS) in a PPS mode;
identifying, through the control circuitry, whether a voltage of a battery is higher than a maximum allowed charging voltage during supply of the charging current to the battery in the PPS mode; and
based on the voltage of the battery being higher than the maximum allowed charging voltage or a current of the battery being higher than a maximum allowed charging current, controlling, through the control circuitry, a gate voltage of each of at least one specified switch of a plurality of switches included in the charging circuitry.
